(19) United States
(12) Patent Application Publication
(10) Pub. No.: US 2024/0405739 A1
(43) Pub. Date: Dec. 5, 2024

(54) Apparatus and Method for Reducing Spectral Distortion in a System for Reproducing Virtual Acoustics via Loudspeakers

(71) Applicant: Fraunhofer-Gesellschaft zur Förderung der angewandten Forschung e.V., München (DE)

(72) Inventors: Adrian LORENZ, Erlangen (DE); Felix WOLF, Erlangen (DE); Simone NEUKAM, Erlangen (DE); Michael LOVEDEE-TURNER, Erlangen (DE)

(21) Appl. No.: 18/804,457

(22) Filed: Aug. 14, 2024

Related U.S. Application Data
(63) Continuation of application No. PCT/EP2023/053119, filed on Feb. 8, 2023.

(30) Foreign Application Priority Data
Feb. 18, 2022 (WO) PCT/EP2022/054125

(51) Int. Cl. H03G 5/16; H04R 3/12; H04R 5/04

(52) U.S. Cl. CPC H03G 5/165; H04R 3/12; H04R 5/04

(57) ABSTRACT

An apparatus for reducing spectral distortion in a system for reproducing virtual acoustics via loudspeakers is provided. The apparatus is configured to reduce the spectral distortion by conducting adaptive equalization and/or by conducting time-dynamic equalization.

### CROSS-REFERENCES TO RELATED APPLICATIONS

This application is a continuation of copending International Application No. PCT/EP2023/053119, filed Feb. 8, 2023, which is incorporated herein by reference in its entirety, and additionally claims priority from International Application No. PCT/EP2022/054125, filed Feb. 18, 2022, which is incorporated herein by reference in its entirety.

The present invention relates to audio signal encoding, audio signal processing and audio signal decoding, and, in particular, to an apparatus and method for reducing spectral distortion in a system for reproducing virtual acoustics.

### BACKGROUND OF THE INVENTION

When sound waves are emitted from loudspeakers to the ears of a listener, the sound is modified multiple times, e.g., by reflections of the sound waves at walls. By this, the sound that arrives at the pinna of the ear comprises, in addition to, e.g., music and speech, also information on the listening environment.

In addition thereto, sound arriving from multiple directions is formed by the head and the pinna of the listener in different ways. Using this information, the brain of the listener is capable to determine an approximated direction and distance of a sound source.

However, if a headphone is employed, usually, all such information is missing, as the audio is almost directly emitted on the eardrums of the listener. By this an impression is created as if the sound would be generated within the head of the listener which may be perceived as inconvenient, and, e.g., spectral coloration may, e.g., occur, in particular, when earphones are employed for a longer time.

It has been determined that the above-described modifications of the sound waves on their way to the pinna and eardrum of the listener can be measured and replicated by digital filters, for example, by employing head-related impulse responses, head-related transfer functions, binaural room impulse responses and binaural room transfer functions. If such filters are applied on audio signals that are to be reproduced by headphones or small earphones, spatial sound is created that creates a realistic sound impression.

Virtual acoustics, also referred to as virtual acoustic space (see [7]) or virtual auditory space, is an audio technology, where sounds presented over headphones appear to originate from any desired spatial direction, and wherein an illusion of one or more virtual sound sources outside the listener's head is created.

Head-Related Transfer Functions (HRTFs) are acoustical transfer functions from sound sources to two ears. HRTFs contain locational information of the corresponding sound sources. A virtual sound from a certain direction can be produced by a convolution of the corresponding HRTFs and an audio signal, when listened to via headphones.

In order to binaurally render spatial sound, HRTFs of the relevant locations around listener are measured and stored. The HRTFs are frequency-dependent and provide essential psychoacoustic cues for a plausible binaural effect.

If, for example, instead of headphones, loudspeaker boxes are used to reproduce a binaural audio signal, a signal reproduced by one of the loudspeaker boxes arrives at both ears and thus, cross-talk would occur. To correctly reproduce a binaural signal through a pair of loudspeakers, this signal is to be prefiltered to compensate for a cross-talk effect that will otherwise significantly damage the spatial characteristics of the binaural signal Cross-talk cancellation (CTC), e.g., applied before playback, shall avoid or at least reduce cross-talk.

To achieve cross-talk cancellation, the applied filter matrices introduce spectral distortion. This may, e.g., be due to extreme dynamics in the phase/magnitude response of the filters. E.g., the spectral dynamics of the cross-talk cancellation filter matrix can reach extreme values in certain frequency bands. This affects an overall timbre and, in particular, the intelligibility, a timbral presence of center sources, and a perceived quality of a cross-talk cancellation-based playback system.

In [1] and [2], concepts for cross-talk cancellation are described. A matrix H

$$H = [ \begin{matrix}{H}_{L L} & {H}_{R L} \\ {H}_{L R} & {H}_{R R}\end{matrix} ]$$

illustrates the transfer functions when two loudspeaker signals

$$y = [ \begin{matrix}{y}_{L} \\ {y}_{R}\end{matrix} ]$$

are replayed by two loudspeaker boxes.

The two signals at the left ear e_{L} and at the right ear e_{R} of a listener can be denoted as:

$$e = [ \begin{matrix}{e}_{L} \\ {e}_{R}\end{matrix} ] = [ \begin{matrix}{H}_{L L} & {H}_{R L} \\ {H}_{L R} & {H}_{R R}\end{matrix} ] [ \begin{matrix}{y}_{L} \\ {y}_{R}\end{matrix} ] .$$

Signal y_{L} is fed into a first loudspeaker box comprising a first loudspeaker L (e.g., a left loudspeaker). Signal y_{R} is fed into a second loudspeaker box comprising a second loudspeaker R. (e.g., a right loudspeaker).

Signal e_{L} is a first signal received at a first ear of a listener (e.g., a left ear of the listener). Signal e_{R} is a second signal received at a second ear of the listener (e.g., a right ear of the listener).

For the first loudspeaker L (e.g., the left loudspeaker) cross-talk coefficient H_{LL} denotes the direct path for said loudspeaker L, and cross-talk coefficient H_{LR} denotes the cross-path for said loudspeaker L.

For the second loudspeaker R (e.g., the right loudspeaker) cross-talk coefficient H_{RR} denotes the direct path for said loudspeaker R, and cross-talk coefficient H_{RL} denotes the cross-path for said loudspeaker R.

H thus describes the modifications of a loudspeaker signal to the ipsilateral and the cross-talk to the contralateral ear (see [1], [2]). In H, the coefficients H_{RL} and H_{LR} denote the cross-talk components that shall be cancelled or at least reduced.

A perfect reconstruction of the signal at the listener's ears, e.g., perfect cross-talk cancellation, would be achieved, if a filter matrix C would be applied on the audio signals x_{L}, x_{R} for the two loudspeakers before the audio signals are output by the two loudspeakers, to obtain two cross-talk cancelled loudspeaker signals:

$$y = [ \begin{matrix}{y}_{L} \\ {y}_{R}\end{matrix} ] = [ \begin{matrix}{C}_{11} & {C}_{12} \\ {C}_{21} & {C}_{22}\end{matrix} ] [ \begin{matrix}{x}_{L} \\ {x}_{R}\end{matrix} ]$$

wherein C is obtained by inversion of the HRTF matrix H according to:

$$C = {H}^{- 1} = \frac{1}{D} [ \begin{matrix}{H}_{RR} & - {H}_{RL} \\ - {H}_{LR} & {H}_{LL}\end{matrix} ] .$$

where D is the determinant given by

$$D = {H}_{LL} {H}_{RR} - {H}_{LR} {H}_{RL} .$$

FIG. 2 illustrates a schema for such a two-channel cross-talk cancellation system.

A perfect cross-talk cancellation system would introduce perfect separation of the ear signals without introducing additional coloration to the binauralized source signal, that is, when the listener is positioned in the sweet spot. In a real-world cross-talk-cancellation-system, however, undesired coloration is, in general, inevitable.

One key factor affecting spectral distortion are the CTC coefficients in C. The inversion of the matrix H is likely an ill-posed problem. In order to achieve sufficient cross-talk cancellation performance, the CTC filter matrix might show extreme spectral dynamics in certain frequency bands.

In an approach of the conventional technology, the dynamics of the filter matrix C are reduced by (frequency-dependent) regularization of the inverse problem (see [3]).

FIG. 3 illustrates an exemplary transfer function matrix H, assuming symmetric HRTFs and total speaker opening angle of 30°.

FIG. 4 illustrates an exemplary transfer function matrix C (H), with low regularization applied, wherein b=10⁻⁷.

FIG. 5 illustrates an exemplary transfer function matrix C (H), with increased regularization applied, wherein b=0.01.

Considering the example of a virtual center component, the summation of direct and cross-talk signals on a single system speaker may cause coloration and may reduce presence (see [4]). Since the input signal to both system channels is correlated, the expected coloration in this case will the different from other cases, such as an ambient component, where cross-talk cancelling filters will be orthogonal to each other.

Some approaches apply a dynamic adaption of a cross-talk cancellation signal.

In some conventional technology approaches appear pre-processing of the input signal is proposed. In U.S. Pat. No. 9,532,156 B2 (see [5]), an apparatus and a method for sound stage enhancement is provided. A spatial ratio is determined from a center component and a side component. The digital audio input signal is adjusted based upon the spatial ratio to form a pre-processed signal. The center component of the cross-talk cancelled signal is realigned to create the final digital audio output.

In U.S. Pat. No. 10,063,984 B2 (see [6]), a method for creating a virtual acoustic stereo system with an undistorted acoustic center is provided. Mid/side separation of a CTC input signal is conducted to apply cross-talk cancellation only to side component and leaving mid component undistorted.

### SUMMARY

An embodiment may have an apparatus for reducing spectral distortion in a system for reproducing virtual acoustics via loudspeakers, wherein the apparatus is configured to reduce the spectral distortion by conducting adaptive equalization and/or by conducting time-dynamic equalization.

Another embodiment may have a system for reproducing virtual acoustics via loudspeakers, wherein the system comprises: a loudspeaker signal generator for generating two or more audio output signals from one or more audio input signals, wherein the system comprises an apparatus according to the invention for reducing spectral distortion, wherein the apparatus is configured to reduce the spectral distortion by conducting adaptive equalization and/or by conducting time-dynamic equalization on at least one of the one or more audio input signals and/or on at least one of the two or more audio output signals and/or on filter information employed by the loudspeaker signal generator on the one or more audio input signals or on one or more processed signals which depend on the one or more audio input signals.

Another embodiment may have a method for reducing spectral distortion in a system for reproducing virtual acoustics via loudspeakers, wherein the method comprises reducing the spectral distortion by conducting adaptive equalization and/or by conducting time-dynamic equalization.

Another embodiment may have a non-transitory digital storage medium having a computer program stored thereon to perform the method for reducing spectral distortion in a system for reproducing virtual acoustics via loudspeakers, wherein the method comprises reducing the spectral distortion by conducting adaptive equalization and/or by conducting time-dynamic equalization, when said computer program is run by a computer.

An apparatus for reducing spectral distortion in a system for reproducing virtual acoustics via loudspeakers is provided. The apparatus is configured to reduce the spectral distortion by conducting adaptive equalization and/or by conducting time-dynamic equalization.

Moreover, a system for reproducing virtual acoustics via loudspeakers is provided. The system comprises a loudspeaker signal generator for generating two or more audio output signals from one or more audio input signals. Furthermore, the system comprises an apparatus according for reducing spectral distortion as described above. The apparatus is configured to reduce the spectral distortion by conducting adaptive equalization and/or by conducting time-dynamic equalization on at least one of the one or more audio input signals and/or on at least one of the two or more audio output signals and/or on filter information employed by the loudspeaker signal generator on the one or more audio input signals or on one or more processed signals which depend on the one or more audio input signals.

Moreover, a method for reducing spectral distortion in a system for reproducing virtual acoustics via loudspeakers is provided. The method comprises reducing the spectral distortion by conducting adaptive equalization and/or by conducting time-dynamic equalization.

Furthermore, a computer program for implementing the above-described method when being executed on a computer or signal processor is provided.

Some embodiments, which aim to counter spectral distortion, may, for example, apply signal component-specific equalizers, e.g., to components of the input signal or the cross-talk cancelled speaker signals, to reduce signal coloration while retaining the obtained virtual spatial image in the designated listening position.

According to some embodiments, it is intended to reduce spectral distortion through a virtual acoustic stereo system by jointly equalizing the two speaker signals depending on the applied cross-talk cancellation filters and similarity information on the cross-talk cancelled signal.

To reduce expected spectral distortions while retaining the intended virtual spatial image, according to an embodiment, a correction filter is applied per output signal frame, which may, e.g., be derived beforehand from summation of the cross-talk-correlation filter matrix. In some embodiments, it may, e.g., be assumed that different signal components, such as a center component, an ambience component and a side component, require different correction filters. In some embodiments, a combination of correction filter sets may, e.g., be determined and may, e.g., be applied depending on the output signal. A benefit is that the applied correction equalizer can be adjusted to improve the timbre for specific components of the input signal.

Some embodiments aim to reduce a timbral distortion to a tolerable level whilst maintaining the CTC-performance, e.g., a “spatial effect”, as good as possible. In some embodiments, a dynamic equalizer (CTC-DynEQ) is employed to moderate the overall timbral distortion of a two-channel processed signal, which may, e.g., operate bufferwise, for example, in the QMF domain, and may, e.g., be user-adjustable.

In an embodiment, the dynamic equalizer may, e.g., act on the output signal by compensating to a variable degree for a level of expected coloration, which may, for example, be approximated by simulating the summation of the active CTC filters within an output speaker path.

According to an embodiment, depending on the expected coloration in three basic cases, for example, a center equalizer (EQ), a side EQ and an ambience EQ, the amplitude response of a set of compensation equalizers may, e.g., be created.

In an embodiment, the applied compensation filter may, for example, be user-adjustable.

According to an embodiment, the applied compensation filter may, e.g., result from a combination of these equalizers, for example, as a function of an inter-channel similarity metric, which may, e.g., be derived from the processed signal. In an embodiment, e.g., a weighting of equalizer components may, e.g., be conducted before combining and/or while combining these equalizers.

Some embodiments provide dynamic equalization for cross-talk cancellation.

According to some embodiments, the input signal is taken into account.

In some embodiments, a timbral correction is applied depending on the input signal component during run-time, where enhancement of the timbre is adjusted specifically to a virtual center signal component, but wherein ambient signals may, e.g., be corrected for differently.

According to an embodiment, an application of the equalization to the input signals and/or to the output signals and/or to the cross-talk cancellation filter matrix may, e.g., be conducted.

In an embodiment, the equalization may, e.g., be determined by conducting calculations based on the cross-talk cancellation coefficients

According to an embodiment, a calculation of equalizer components may, e.g., be conducted based on a combination of the complex cross-talk cancellation coefficients in a frequency domain.

In an embodiment, linear combinations of the complex cross-talk cancellation coefficients may, e.g., be employed to calculate equalizer components.

According to an embodiment, multiple equalizer components to a single correction equalizer may, e.g., be combined.

In an embodiment, the equalizer components may, e.g., be weighted before a combination to a single correction equalizer.

According to an embodiment, the combination of the equalizer components may, e.g., be updated at specific times based on one or more specific properties of the signal.

In an embodiment, the equalizer may, e.g., be updated depending on information on a signal similarity.

According to an embodiment, the equalizer may, e.g., be updated depending on the signal similarity in one or more frequency bands.

In an embodiment, the equalizer may, e.g., be updated based on the average similarity of multiple frequency bands.

According to an embodiment, an additional weighting may, e.g., be employed before calculating the average.

In an embodiment, a magnitude-based weighting may, e.g., be employed.

According to an embodiment, the factor obtained from the signal similarity may, e.g., be weighted with a specific weighting function.

In an embodiment, a sigmoid function may, e.g., be employed as weighting function.

According to an embodiment, the magnitude of the frequency bands may, e.g., be employed to detect, which frequency bands are used to calculate similarity information.

In an embodiment, a specific number of frequency bands with the highest magnitude may, e.g., be employed to calculate the similarity information.

Some embodiments relate to head related transfer functions and/or to a cross-talk-cancellation filter matrix, for example, for two speakers, for example on mobile devices.

In some embodiments, a reduction of spectral distortion and/or reduction of timbral distortion is aimed to be achieved. According to some embodiment, a post-processing of cross-talk cancelled signals may, e.g., be conducted.

A signal similarity of cross-talk cancelled signals and/or filter magnitudes based on addition of cross-talk cancellation coefficients may, e.g., be determined. Equalization for mid, side ambient signals may, e.g., be provided, for example, to achieve distortion free center for cross-talk cancellation and/or center enhancement for cross-talk cancellation, e.g., by employing dynamic equalization.

### BRIEF DESCRIPTION OF THE DRAWINGS

Embodiments of the present invention will be detailed subsequently referring to the appended drawings, in which:

FIG. 1a illustrates an apparatus for reducing spectral distortion according to an embodiment.

FIG. 1b illustrates an embodiment, wherein the apparatus of FIG. 1a and a system for reproducing virtual acoustics via loudspeakers interact with each other, but wherein the apparatus of FIG. 1a is not part of the system.

FIG. 1c illustrates a system for reproducing virtual acoustics via loudspeakers according to an embodiment, wherein the system comprises the apparatus of FIG. 1a.

FIG. 2 illustrates a schema for a two-channel cross-talk cancellation system.

FIG. 3 illustrates an exemplary transfer function matrix assuming symmetric head-related transfer functions.

FIG. 4 illustrates an exemplary transfer function matrix with low regularization applied.

FIG. 5 illustrates an exemplary transfer function matrix with increased regularization applied.

FIG. 6 illustrates a generation of a center equalizer according to an embodiment.

FIG. 7 illustrates a generation of a side equalizer according to an embodiment.

FIG. 8 illustrates a generation of an ambience equalizer according to an embodiment.

FIG. 9 illustrates a sigmoid activation function according to an embodiment.

FIG. 10 illustrates an example for a resulting equalizer according to an embodiment.

FIG. 11 illustrates an average gain over all subbands introduced by an example dynamic equalizer according to an embodiment.

### DETAILED DESCRIPTION OF THE INVENTION

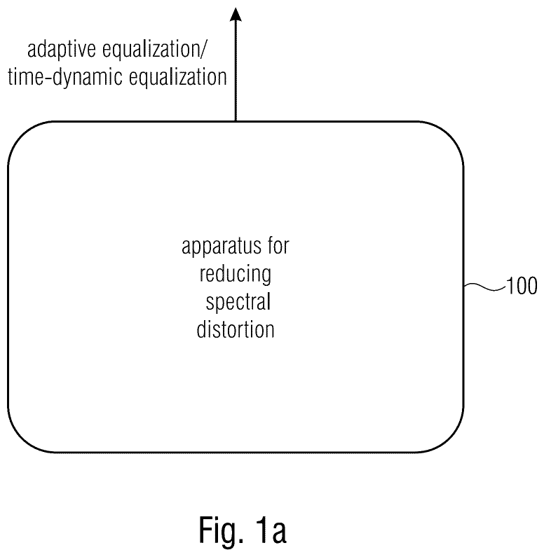

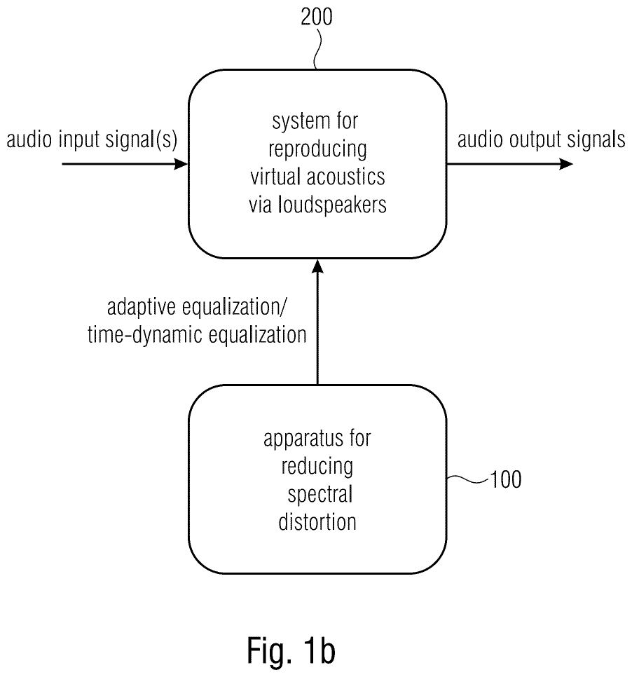

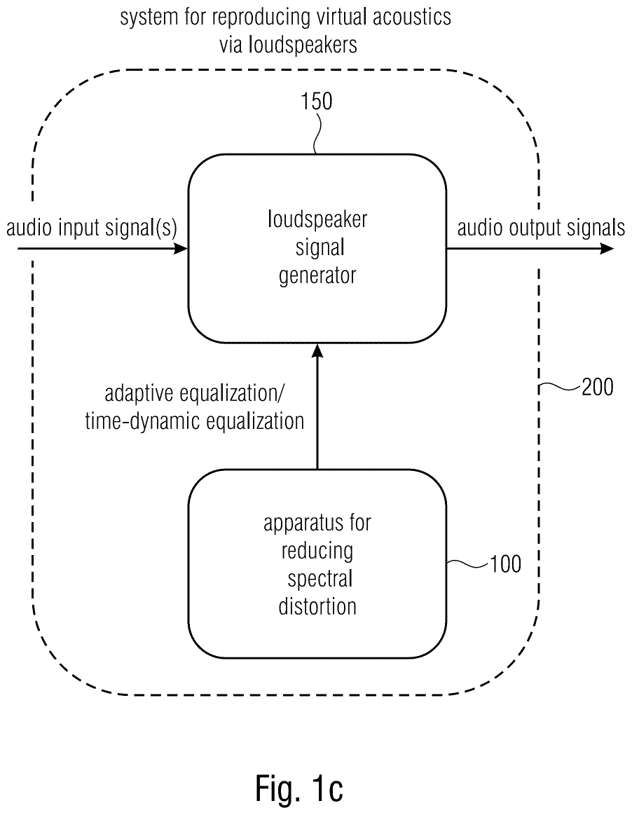

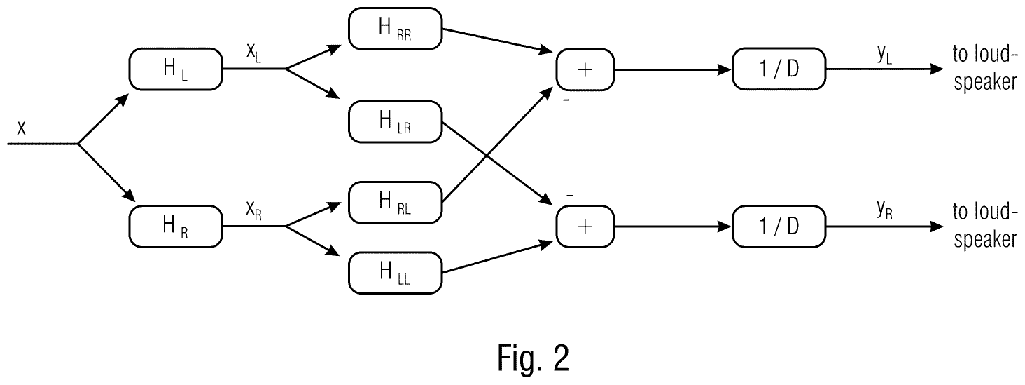

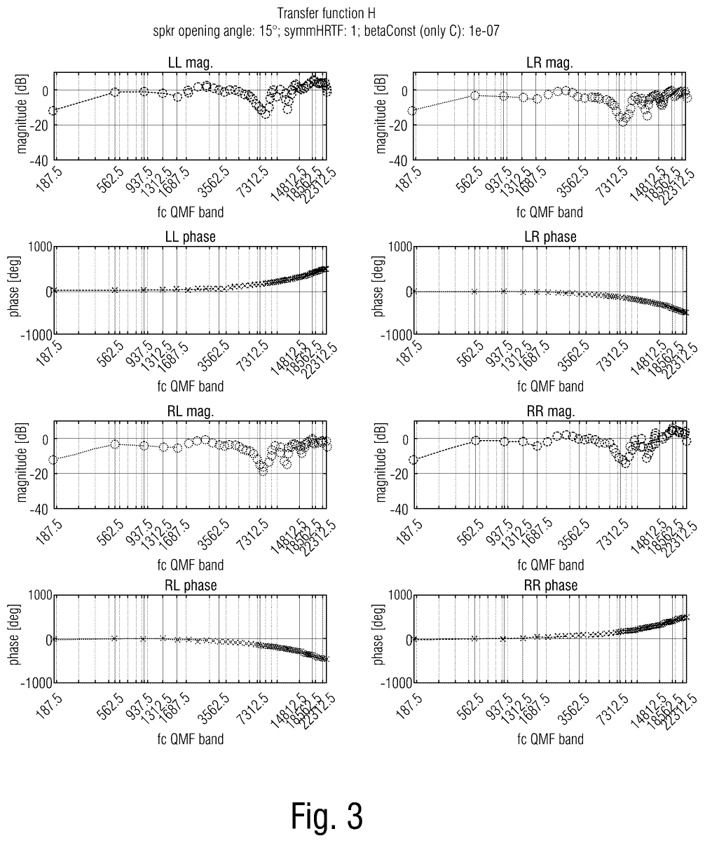

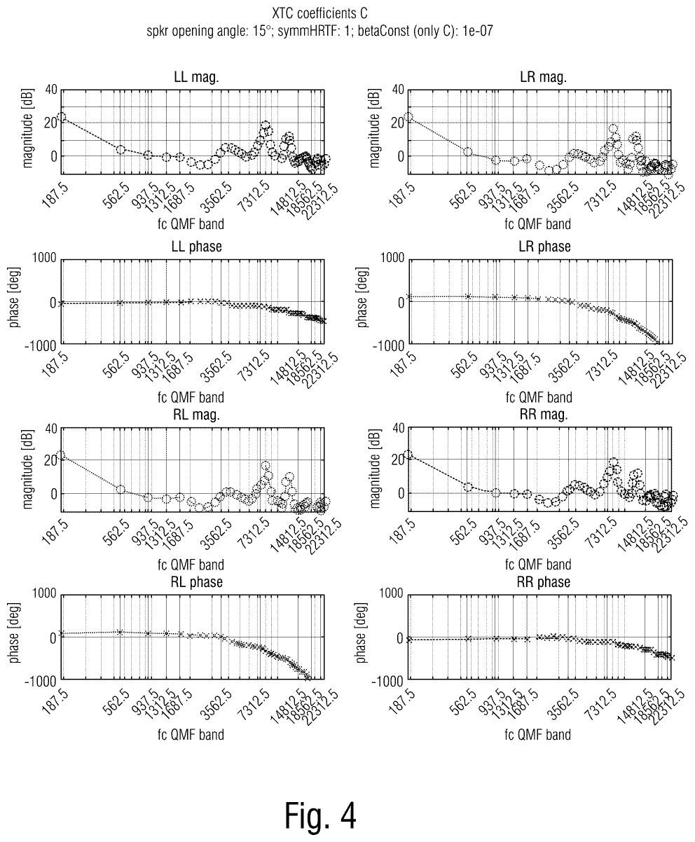

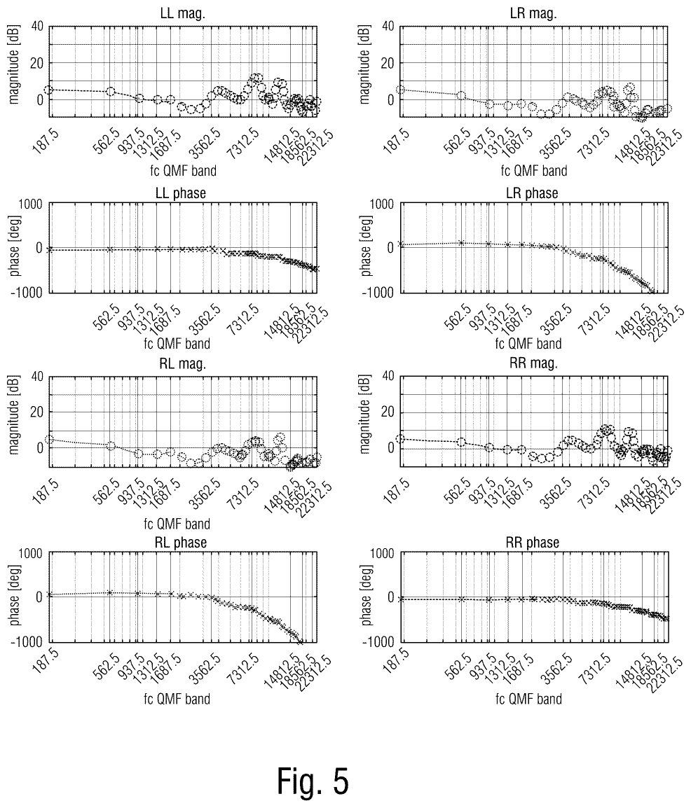

FIG. 1a illustrates an apparatus 100 for reducing spectral distortion in a system 200 for reproducing virtual acoustics via loudspeakers according to an embodiment.

The apparatus 100 is configured to reduce the spectral distortion by conducting adaptive equalization and/or by conducting time-dynamic equalization.

FIG. 1b illustrates an embodiment, wherein the apparatus 100 for reducing spectral distortion of FIG. 1a and the system 200 for reproducing virtual acoustics via loudspeakers interact with each other, but wherein the apparatus 100 of FIG. 1a is not part of the system 200. In other words, in the embodiment of FIG. 1b, the system 200 does not comprise the apparatus 100.

FIG. 1c illustrates a system 200 for reproducing virtual acoustics via loudspeakers according to an embodiment. In contrast to the embodiment of FIG. 1b, in the embodiment of FIG. 1c, the apparatus 100 of FIG. 1a is part of the system 200. In other words, in the embodiment of FIG. 1c, the system 200 comprises the apparatus 100.

The following particular embodiments relate to the embodiment of FIG. 1a, as well as to the embodiment of FIG. 1b, as well as to the embodiment of FIG. 1c.

According to an embodiment, the apparatus 100 may, e.g., be configured to reduce the spectral distortion by conducting the adaptive equalization and/or by conducting the time-dynamic equalization on at least one of one or more audio input signals of the system 200 for reproducing virtual acoustics, and/or on at least one of two or more audio output signals of the system 200 and/or on filter information to be applied by the system 200 on the one or more audio input signals or on one or more processed signals which depend on the one or more audio input signals.

In an embodiment, the apparatus 100 may, e.g., be configured to determine equalization information depending on at least two of the audio input signals and/or depending on at least two of the audio output signals and/or depending on at least two of the processed signals. The apparatus 100 may, e.g., be configured to conduct the adaptive equalization and/or by conducting the time-dynamic equalization by employing the equalization information.

According to an embodiment, the system 200 for reproducing virtual acoustics comprises a cross-talk cancellation system 200 for conducting cross-talk cancellation to remove and/or to reduce and/or to avoid cross-talk created by the system 200 when reproducing the virtual acoustics via the loudspeakers. The apparatus 100 may, e.g., be configured to reduce spectral distortion resulting from conducting the cross-talk cancellation.

In an embodiment, the apparatus 100 comprises an equalizer. The apparatus 100 may, e.g., be configured to update the equalizer at specific times.

According to an embodiment, the apparatus 100 may, e.g., be configured to determine similarity information by determining information on a similarity of at least two audio signals. The apparatus 100 may, e.g., be configured to conduct the adaptive equalization and/or the time-dynamic equalization using the similarity information. Moreover, the one or more audio input signals of the system 200 comprise the at least two audio signals, or wherein the two or more audio output signals of the system 200 comprise the at least two audio signals, or wherein the one or more processed signals comprise the at least two audio signals.

In an embodiment, to determine the similarity information, the apparatus 100 may, e.g., be configured to determine information on a similarity of at least two audio signals in each of one or more frequency bands. The apparatus 100 may, e.g., be configured to conduct the adaptive equalization and/or the time-dynamic equalization by employing the information on the similarity of the signals in each of the one or more frequency bands.

According to an embodiment, to determine the similarity information the apparatus 100 may, e.g., be configured to determine an average of a similarity of at least two audio signals in each of a plurality of frequency bands. The apparatus 100 may, e.g., be configured to conduct the adaptive equalization and/or the time-dynamic equalization by employing the average of the similarity of the signals in each of the plurality of frequency bands.

In an embodiment, to determine the similarity information, the apparatus 100 may, e.g., be configured to determine a magnitude-based weighted similarity by conducting a magnitude-based weighting of a similarity of at least two audio signals in each of a plurality of frequency bands. The apparatus 100 may, e.g., be configured to conduct the adaptive equalization and/or the time-dynamic equalization by employing the magnitude-based weighted similarity.

According to an embodiment, the apparatus 100 may, e.g., be configured to conduct the magnitude-based weighting by employing a weighting function.

In an embodiment, the weighting function may, e.g., be a sigmoid function.

According to an embodiment, the apparatus 100 may, e.g., be configured to determine a proper subset of one or more frequency bands from a plurality of frequency bands by employing a magnitude of each of the plurality of frequency bands of the at least two audio signals for determining the proper subset. The apparatus 100 may, e.g., be configured to determine the similarity information by determining a similarity information for each of one or more frequency bands of the proper subset without determining similarity information for each of the one or more frequency bands of the plurality of frequency bands which are not comprised by the proper subset.

In an embodiment, each frequency of the plurality of frequency bands may, e.g., be associated with a magnitude that depends on a magnitude of said frequency band of one or more of the at least two audio signals. The apparatus 100 may, e.g., be configured to determine the proper subset of one or more frequency bands such that the magnitude being associated with each frequency band of the one or more frequency bands of the proper subset may, e.g., be greater than or equal to the magnitude being associated with each of the one or more frequency bands of the plurality of frequency bands which are not comprised by the proper subset.

According to an embodiment, the system 200 for reproducing virtual acoustics may, e.g., be configured to conduct cross-talk cancellation by employing a plurality of cross-talk cancellation coefficients. The apparatus 100 may, e.g., be configured to reduce the spectral distortion by conducting adaptive equalization and/or by conducting time-dynamic equalization using a plurality of equalizer components.

The apparatus 100 may, e.g., be configured to determine the plurality of equalizer components depending on one or more of the plurality of cross-talk cancellation coefficients.

In an embodiment, the apparatus 100 may, e.g., be configured to determine the plurality of equalizer components by choosing, depending on the cross-talk cancellation coefficients, a pre-calculated set of equalizer components from two or more pre-calculated sets of equalizer components.

In an embodiment, the apparatus 100 may, e.g., be configured to determine the plurality of equalizer components at run-time depending on the similarity information indicating the information on the similarity of the at least two audio signals and/or depending on the plurality of cross-talk cancellation coefficients.

According to an embodiment, the apparatus 100 may, e.g., be configured to determine the plurality of equalizer components by determining one or more combinations of the plurality of cross-talk cancellation coefficients being a plurality of complex cross-talk cancellation coefficients in a frequency domain.

In an embodiment, to determine the one or more combinations of the plurality of cross-talk cancellation coefficients for determining the plurality of equalizer components, the apparatus 100 may, e.g., be configured to determine one or more linear combinations of the complex cross-talk cancellation coefficients in the frequency domain.

According to an embodiment, the apparatus 100 may, e.g., be configured to determine a single correction equalizer from the plurality of equalizer components.

In an embodiment, the apparatus 100 may, e.g., be configured to determine the single correction equalizer from the plurality of equalizer components by weighting the plurality of equalizer components before combining the plurality of equalizer components to obtain the single correction equalizer.

According to an embodiment, the apparatus 100 may, e.g., be configured to weight the plurality of equalizer components depending on a similarity value, wherein the similarity value depends on the similarity information.

In an embodiment, the apparatus 100 may, e.g., be configured to conduct adaptive equalization and/or by conducting time-dynamic equalization on one or more audio input signals of the system 200 for reproducing the virtual acoustics.

According to an embodiment, the apparatus 100 may, e.g., be configured to conduct adaptive equalization and/or by conducting time-dynamic equalization on two or more audio output signals of the system 200 for reproducing the virtual acoustics.

In an embodiment, the apparatus 100 may, e.g., be configured to conduct adaptive equalization and/or by conducting time-dynamic equalization on a cross-talk cancellation filter matrix employed for cross-talk cancellation by the system 200 for reproducing the virtual acoustics.

FIG. 1c illustrates a system 200 for reproducing virtual acoustics via loudspeakers according to an embodiment.

The system 200 of FIG. 1c comprises a loudspeaker signal generator 150 for generating two or more audio output signals from one or more audio input signals,

Moreover, the system 200 of FIG. 1c comprises the apparatus 100 of FIG. 1a for reducing spectral distortion.

In the system 200 of FIG. 1c, the apparatus 100 is configured to reduce the spectral distortion by conducting adaptive equalization and/or by conducting time-dynamic equalization on at least one of the one or more audio input signals and/or on at least one of the two or more audio output signals and/or on filter information employed by the loudspeaker signal generator 150 on the one or more audio input signals or on one or more processed signals which depend on the one or more audio input signals.

According to an embodiment, the system 200 for reproducing virtual acoustics may, e.g., comprise a cross-talk cancellation system for conducting cross-talk cancellation (not shown) to remove and/or to reduce and/or to avoid cross-talk created by the system for conducting cross-talk cancellation when reproducing the virtual acoustics via the loudspeakers. The apparatus 100 may, e.g., be configured to reduce spectral distortion resulting from conducting the cross-talk cancellation.

In an embodiment, the one or more audio input signals may, e.g., comprise two binaural audio signals.

According to an embodiment, the system 200 of FIG. 1c, for example, comprises the loudspeakers. In another embodiment, the system of FIG. 1c, for example, does not comprise the loudspeakers.

In an embodiment, the apparatus 100 may, e.g., be configured to conduct the adaptive equalization and/or to conduct the time-dynamic equalization by applying an average gain over two or more subbands, e.g., for achieving loudness preservation. In a particular embodiment, the apparatus 100 may, for example, be configured to apply the average gain over all subbands.

In the following, particular embodiments of the present invention are described.

In embodiments, to counter expected coloration, a correction equalizer may, e.g., be applied, for example, on the cross-talk-cancelled speaker signal, for example, in the QMF domain. According to an embodiment, by a summation depending on a complex CTC filter matrix, e.g., three, correction filters may, e.g., be determined/estimated for an expected magnitude response for, e.g., three, basic signal component cases.

For example, for a mid component case, a mid/center equalizer (EQ_{mid}/EQ_{center}) may, e.g., be determined. And/or, for example, for a side component case, a side equalizer (EQ_{side}) may, e.g., be determined. And/or, for example, for an ambience component case, an ambience equalizer (EQ_{amb}) may, e.g., be determined. E.g., the terms mid equalizer and center equalizer may, e.g., be used interchangeably.

According to an embodiment, a combination of the three component equalizers may, e.g., determine the applied equalizer (the equalizer to be applied). This may, e.g., depend on signal similarity information with respect to an output signal and/or may, e.g., depend on manual tuning of the component weights.

In the following, determining component equalizers according to some embodiments is described.

According to some embodiments, two or more, e.g., three, component equalizers (also referred to as equalizer components) may, e.g., be determined. The determination of the three component equalizers may, for example, be conducted before run-time. For example, the component equalizers may, e.g., be determined as described in the following.

Some embodiments are based on the finding that an expected coloration of a two-channel input signal s with the inter-channel phase difference (IPD) per band IPD(b) may, e.g., be estimated based on a resulting amplitude spectrum Cₛₚ(b) per QMF band b at speaker index sp. It depends on the summation of the CTC-filters for the direct path Hₛₚ_{₁₁} and the cross-path Hₛₚ_{_{X}} per speaker:

$${C}_{sp} ( IPD , b ) = \vert {H}_{{sp}_{II}} ( b ) + {e}^{i \cdot IPD} {H}_{{sp}_{X}} ( b ) \vert$$

The magnitude response of a center equalizer EQ_{center} may, e.g., compensate for the expected coloration of a two-channel input signal s_{center} with the IPD center (b)=0° over all bands (e.g. phantom center image), averaged over both speakers.

The magnitude response of a side equalizer EQ_{side} may, e.g., compensate for the expected coloration of a two-channel input signal s_{side} with the IPD side (b)=180°, averaged over both speakers.

For the case of an ambient equalizer EQ_{amb} left and right input signals may, e.g., be uncorrelated. The average expected coloration per speaker may, e.g., assume unit power of input spectra.

$$\begin{matrix}{EQ}_{center} ( b ) = \frac{1}{2} {\sum }_{i = 1}^{2} {\vert {H}_{{sp}_{II}} ( b ) + {H}_{{sp}_{X}} ( b ) \vert}^{- 1} \\ {EQ}_{side} ( b ) = \frac{1}{2} {\sum }_{i = 1}^{2} {\vert {H}_{{sp}_{II}} ( b ) - {H}_{{sp}_{X}} ( b ) \vert}^{- 1} \\ {EQ}_{amb} ( b ) = \frac{1}{2} {\sqrt{{\sum }_{i = 1}^{2} {\vert {H}_{{sp}_{II}} ( b ) \vert}^{2} + {\vert {H}_{{sp}_{X}} ( b ) \vert}^{2}}}^{- 1}\end{matrix}$$

In the above equations, i may, e.g., denote the speaker index: i=sp.

In the following, taking the speaker signal similarity into account according to some embodiments is described.

In some embodiments, a speaker signal similarity may, e.g., be obtained/determined, for example, per input buffer. For example, the speaker signal similarity may, e.g., be obtained during run-time.

To modulate the frequency response of a resulting compensation equalizer, according to an embodiment, a similarity vector \vec{r}_{ws}(t) may, e.g., be derived for each input buffer t, for example, after cross-talk cancellation has been applied. \vec{S}_{L}(t, b) and \vec{S}_{R}(t, b) may, e.g., indicate the two-channel complex valued signal per buffer and frequency band.

\vec{r}_{w}(t) may, e.g., indicate a combination of the similarity metric \vec{r}(t, b) for bands 0 and 1, e.g., weighted by w_{QMF}(t). A sigmoidal function in \vec{r}_{ws}(t) intends to tilt the values of \vec{r}_{w}(t) to favor boundary cases (s_{center}, s_{side}).

In an embodiment, the amplitude of only the first two frequency bands (b=0, 1) may, e.g., be considered. In another embodiment, however, at first, the two QMF bands with the highest magnitude may, e.g., determined and may, e.g., instead be chosen for signal similarity estimation and weighting. This increases stability.

In order to stabilize the similarity vector \vec{r}_{w}(t), a weighting factor w_{QMF}(t) may, e.g., be employed, which introduces a relative weight between the inter-channel similarity values. It may, e.g., depend on the distribution of input levels between the two QMF bands over input channels. A low signal amplitude in one frequency band may, e.g., have a disproportionate effect on the resulting similarity vector. For example, if useful signal is only present in QMF band 1, and band 2 consists only of a low amplitude noise floor, the resulting similarity value may show unpredictable behavior between adjacent input buffers.

w_{sigm} reduces the range of possible values slightly, and can be adjusted between 0 and 1

$${\vec{r}}_{ws} ( t ) = \frac{{\vec{r}}_{w} ( t )}{{w}_{sigm} + \vert {\vec{r}}_{w} ( t ) \vert}$$

$$\{ {\vec{r}}_{ws} ∈ ℝ ‖ - 1 \leq {\vec{r}}_{ws} \geq 1 \}$$

$${\vec{r}}_{w} ( t ) = {\vec{w}}_{QMF} ( t ) \cdot \vec{r} ( t , 0 ) + ( 1 - {\vec{w}}_{QMF} ( t ) ) \cdot \vec{r} ( t , 1 )$$

$$\vec{r} ( t , b ) = \frac{\vert {\vec{S}}_{L} ( t , b ) \vert + \vert {\vec{S}}_{R} ( t , b ) \vert}{max \{ \vert {\vec{S}}_{L} ( t , b ) \vert , \vert {\vec{S}}_{R} ( t , b ) \vert \}}$$

$$b = \{ 0 , 1 \}$$

$${w}_{QMF} ( t ) = \frac{1}{2} ( \frac{\vert {\vec{S}}_{L} ( t , 1 ) \vert}{\vert {\vec{S}}_{L} ( t , 1 ) \vert + \vert {\vec{S}}_{L} ( t , 2 ) \vert} + \frac{\vert {\vec{S}}_{R} ( t , 1 ) \vert}{\vert {\vec{S}}_{R} ( t , 1 ) \vert + \vert {\vec{S}}_{R} ( t , 2 ) \vert} )$$

$$or , for example ,$$

$${w}_{QMF} ( t ) = \frac{1}{2} ( \frac{\vert {\vec{S}}_{L} ( t , 0 ) \vert}{\vert {\vec{S}}_{L} ( t , 0 ) \vert + \vert {\vec{S}}_{L} ( t , 1 ) \vert} + \frac{\vert {\vec{S}}_{R} ( t , 0 ) \vert}{\vert {\vec{S}}_{R} ( t , 0 ) \vert + \vert {\vec{S}}_{R} ( t , 1 ) \vert} )$$

In the following, it is described how, according to some embodiments, a resulting equalization is obtained by combining a similarity vector and/or manual tuning factors.

According to a particular embodiment, the applied equalizer's magnitude, e.g., a dynamic equalizer Dyn_{EQ}(b) or Dyn_{EQ}(t, b), may, e.g., combine the ambience equalizer EQ_{amb}(b) with either the side equalizer EQ_{side}(b) or with the center equalizer EQ_{center}(b). The factors e_{center}, e_{side} and e_{amb} may, for example, be calculated once per input buffer. They may, e.g., depend on the similarity vector \vec{r}_{ws} and/or on tuning parameters weight_{center} and/or weight_{side} and/or weight_{amb}, which may, e.g., be user-adjustable tuning parameters, for example, ranging from 0 to 1. Relative weighting the equalizer components may, e.g., be adjustable to balance spatial and timbral impression of a system.

$${e}_{center} ( t ) = \{ \begin{matrix}{\vec{r}}_{ws} ( t ) \cdot {weight}_{center} , & if {\vec{r}}_{ws} ( t ) < 0 \\ 0 , & otherwise\end{matrix}$$

$${e}_{side} ( t ) = \{ \begin{matrix}{\vec{r}}_{ws} ( t ) \cdot {weight}_{side} , & if {\vec{r}}_{ws} ( t ) > 0 \\ 0 , & otherwise\end{matrix}$$

$${e}_{amb} ( t ) = ( 1 - \vert {\vec{r}}_{ws} ( t ) \vert ) \cdot {weight}_{amb}$$

$${EQ}_{center / side} ( t , b ) = {{EQ}_{center} ( b )}^{{e}_{center} ( t )} \cdot {{EQ}_{side} ( b )}^{{e}_{side} ( t )}$$

$${Dyn}_{EQ} ( t , b ) = - 1 + {{EQ}_{center / side} ( b )}^{1 - exp ( t )} \cdot {{EQ}_{amb} ( b )}^{{e}_{amb} ( t )}$$

For example, exp(t) may, e.g., be exp(t)=e_{amb}(t), such that:

$${Dyn}_{EQ} ( t , b ) = - 1 + {{EQ}_{center / side} ( b )}^{1 - {e}_{amb} ( t )} \cdot {{EQ}_{amb} ( b )}^{{e}_{amb} ( t )}$$

According to embodiments, the resulting equalizer may, for example, be applied to the output speaker signal.

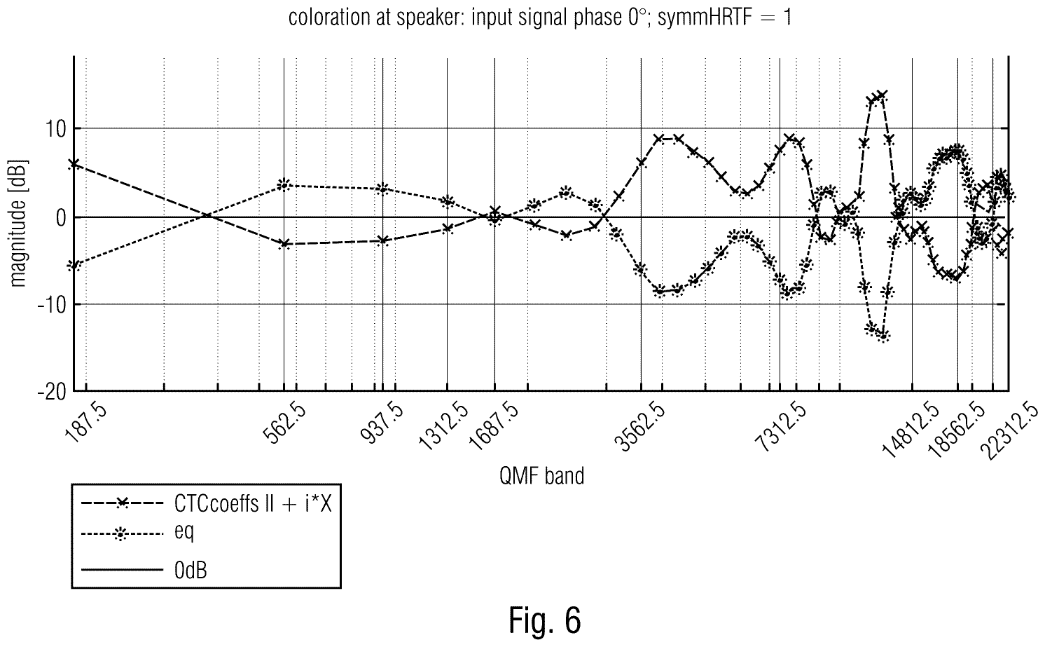

FIG. 6 to FIG. 11 illustrate examples for the provided embodiments visually.

FIG. 6 illustrates a generation of a center equalizer (EQ) according to an embodiment. The x-axis labels denote the center frequencies of the QMF bands.

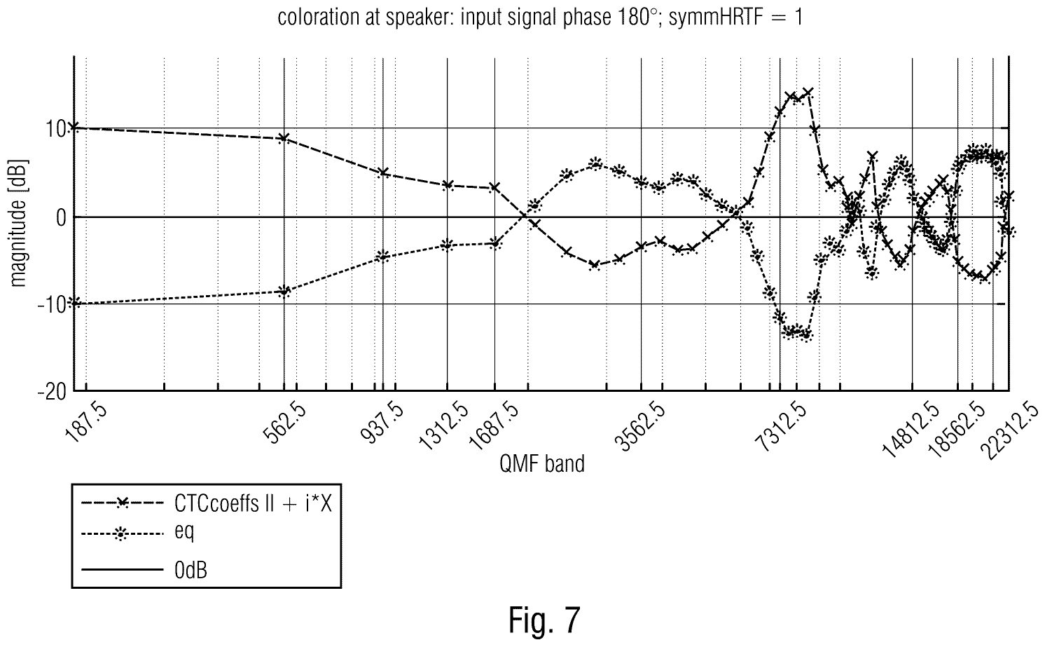

FIG. 7 illustrates a generation of a side equalizer according to an embodiment.

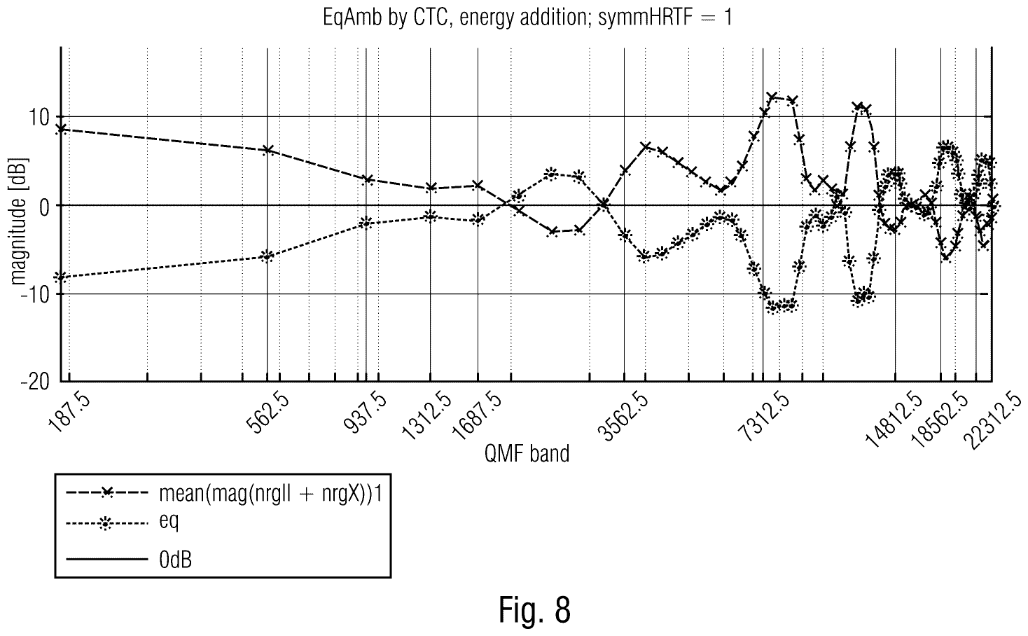

FIG. 8 illustrates a generation of an ambience equalizer according to an embodiment.

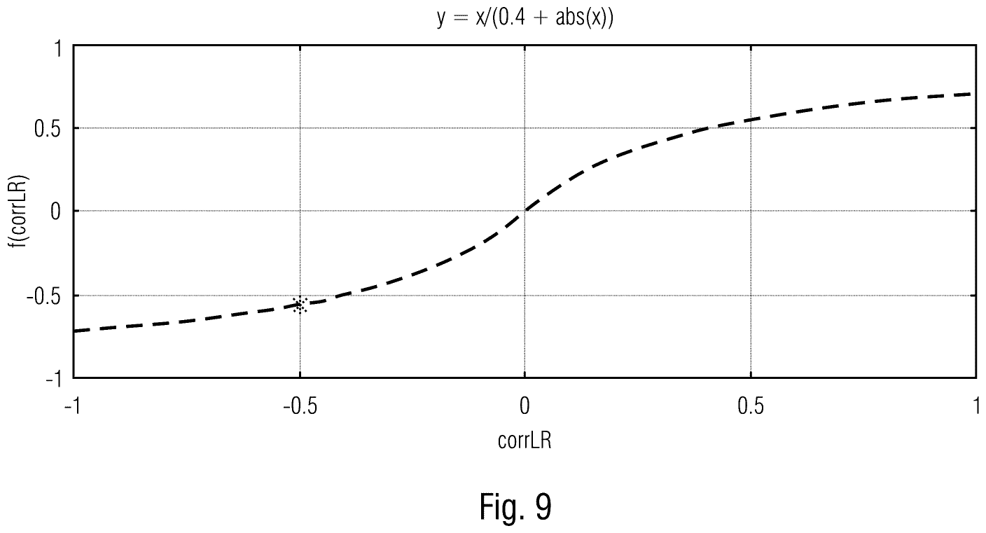

FIG. 9 illustrates a sigmoid activation function for a signal similarity value −0.5 and a weight 0.4 according to an embodiment.

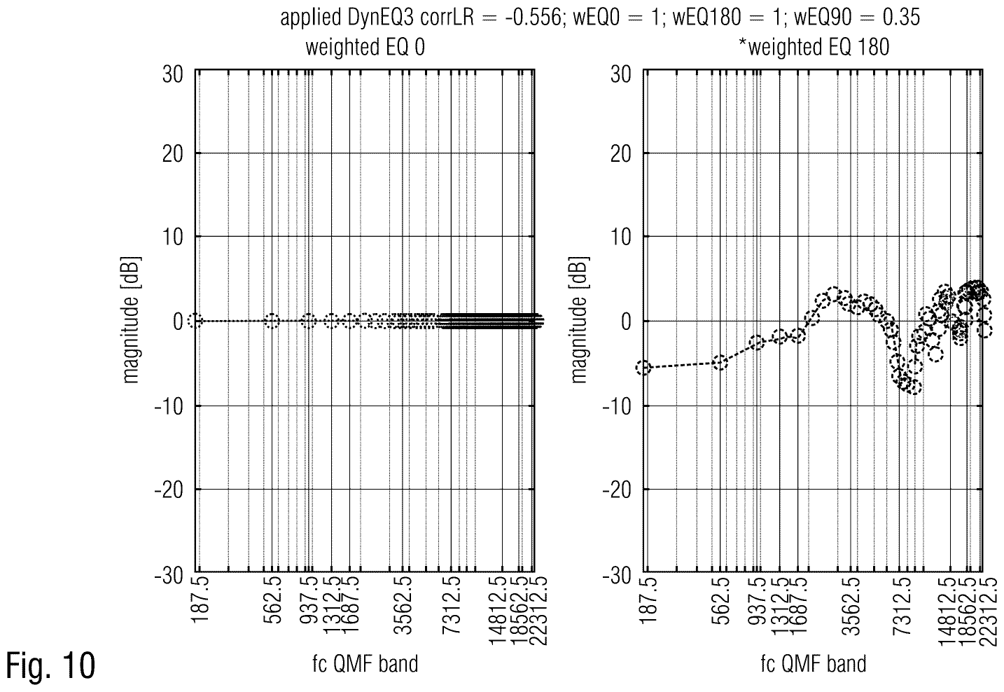

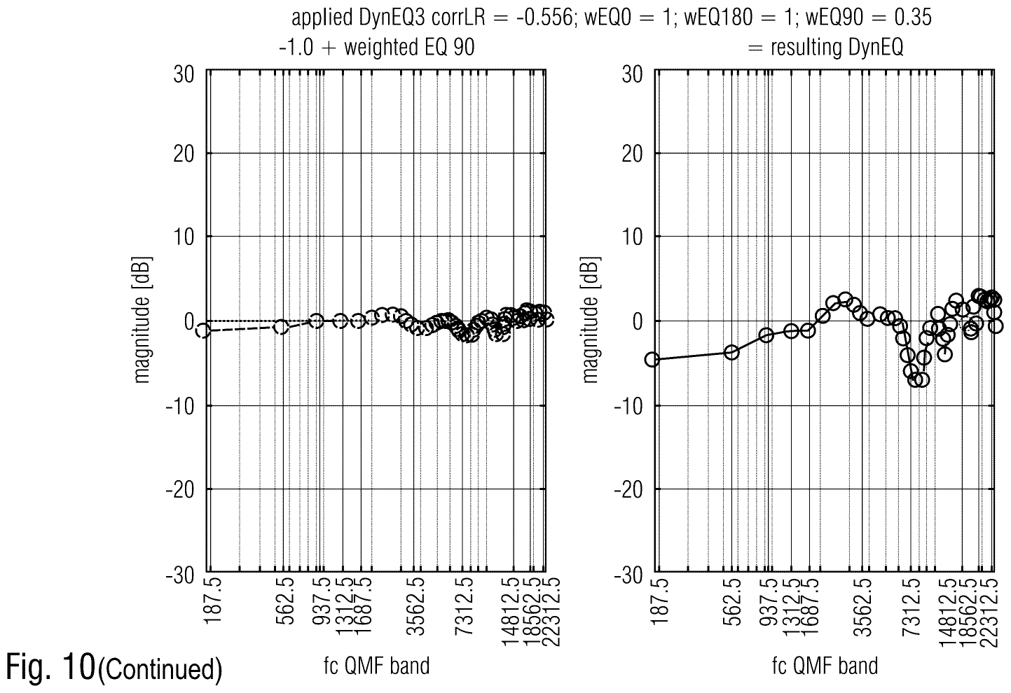

FIG. 10 illustrates an example for a resulting equalizer according to an embodiment. ambience EQ is labeled “EQ 90”.

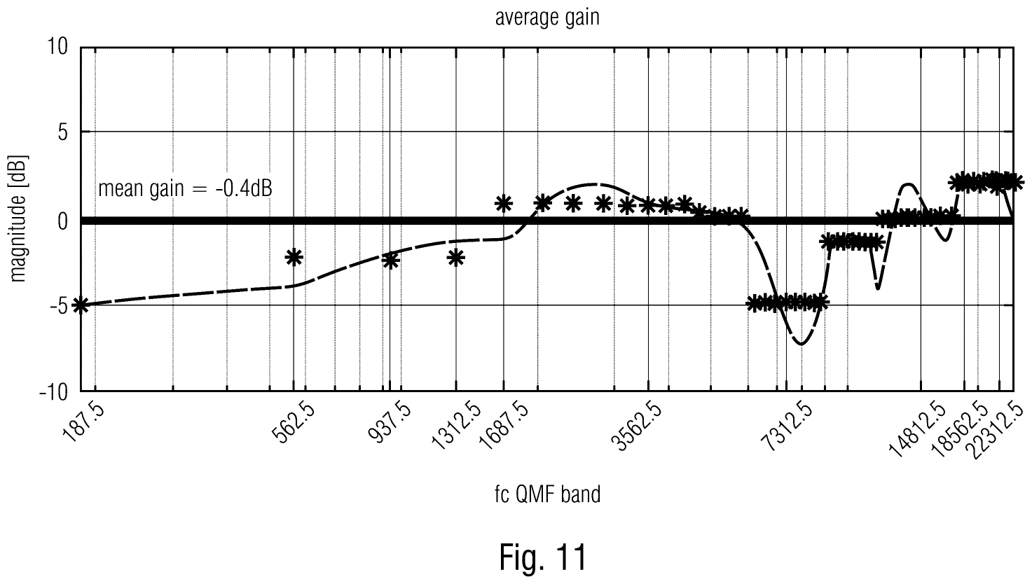

FIG. 11 illustrates an average gain over all subbands introduced by an example dynamic equalizer (DynEQ) according to an embodiment.

Concepts of the present invention, may, for example, be employed in another domain, e.g., another frequency domain, e.g., in the FFT domain instead of the QMF domain. Some embodiments may, for example, be implemented in an Fast Fourier Transform (FFT) domain.

In an embodiment, a selection of QMF bands may, e.g., be employed for signal similarity estimation: In an implementation (for example, in a headphone library headphonelib) the speaker signal similarity may, e.g., be based on the two bands with the highest magnitudes. By this, stability may, e.g., employed for cases where signal energy in bands 0 and 1 are low.

According to an embodiment, the apparatus 100 may, e.g., be configured to reduce the spectral distortion by conducting the adaptive equalization in a loudness-preserving way, and/or by conducting the time-dynamic equalization in a loudness-preserving way, and/or by adjusting the one or more audio input signals to ensure loudness-preservation. E.g., loudness preservation may, e.g., be assured through an applied equalizer. One could counter this by applying a makeup gain factor to the component equalizers or the applied equalizer and/or the signals, so that the average or root mean square (RMS) volume of an output signal is not affected.

In an embodiment, different configurations for the component equalizer magnitude responses may, e.g., be employed. The above approach to estimate the component correction filter magnitudes may, e.g., be varied. Variations may, e.g., relate to the summation of the complex CTC filters, for example, by applying a variable weighting to specific frequency regions. According to an embodiment, a weighting between direct- and cross-talk components may, e.g., be introduced to specifically address coloration by one component. In another embodiment, the equalizer components may, e.g., be computed at run-time.

According to an embodiment, a (for example frequency selective) compression or expansion of the spectral dynamics for specific frequency regions of the component or applied filter may, e.g., be employed. According to another embodiment, the equalizer components may, e.g., be computed at run-time.

In an embodiment, a different combination of component equalizers may, e.g., be applied. For example, the center equalizer (EQ_{center}) and the side equalizer (EQ_{side}) magnitudes may, e.g., be summed to create the ambience equalizer (EQ_{amb}). For intermediate cases, for example, where similarity between a left signal and a right signal (corrLR) is at +−0.5, it is not guaranteed that the applied equalizer matches well with a model of an assumed coloration. A variation and/or combination of the component equalizers may, e.g., realize a suitable approach. For example, a complex addition of the correction EQs may, e.g., be conducted.

According to an embodiment, a constrained optimization approach may, e.g., be employed. A filter to be applied may, e.g., be generated for each frequency band with respect to its signal similarity, while considering an expected cross-talk cancellation in the sweet spot within this band.

In the following, further embodiments are provided:

Embodiment 1: An apparatus (100) for reducing spectral distortion in a system (200) for reproducing virtual acoustics via loudspeakers,
wherein the apparatus (100) is configured to reduce the spectral distortion by conducting adaptive equalization and/or by conducting time-dynamic equalization.

Embodiment 2: An apparatus (100) according to embodiment 1,
wherein the apparatus (100) is configured to reduce the spectral distortion by conducting the adaptive equalization and/or by conducting the time-dynamic equalization on at least one of one or more audio input signals of the system (200) for reproducing virtual acoustics, and/or on at least one of two or more audio output signals of the system (200) and/or on filter information to be applied by the system (200) on the one or more audio input signals or on one or more processed signals which depend on the one or more audio input signals.

Embodiment 3: An apparatus (100) according to embodiment 2,
wherein the apparatus (100) is configured to determine equalization information depending on at least two of the audio input signals and/or depending on at least two of the audio output signals and/or depending on at least two of the processed signals, and
wherein the apparatus (100) is configured to conduct the adaptive equalization and/or by conducting the time-dynamic equalization by employing the equalization information.

Embodiment 4: An apparatus (100) according to embodiment 2 or 3,
wherein the system (200) for reproducing virtual acoustics comprises a cross-talk cancellation system (200) for conducting cross-talk cancellation to remove and/or to reduce and/or to avoid cross-talk created by the system (200) when reproducing the virtual acoustics via the loudspeakers,
wherein the apparatus (100) is configured to reduce spectral distortion resulting from conducting the cross-talk cancellation.

Embodiment 5: An apparatus (100) according to one of embodiments 2 to 4,
wherein the apparatus (100) comprises an equalizer,
wherein the apparatus (100) is configured to update the equalizer at specific times.

Embodiment 6: An apparatus (100) according to one of embodiments 2 to 5,
wherein the apparatus (100) is configured to determine similarity information by determining information on a similarity of at least two audio signals, and
wherein the apparatus (100) is configured to conduct the adaptive equalization and/or the time-dynamic equalization using the similarity information,
wherein the one or more audio input signals of the system (200) comprise the at least two audio signals, or wherein the two or more audio output signals of the system (200) comprise the at least two audio signals, or wherein the one or more processed signals comprise the at least two audio signals.

Embodiment 7: An apparatus (100) according to embodiment 6,
wherein, to determine the similarity information, the apparatus (100) is configured to determine information on a similarity of at least two audio signals in each of one or more frequency bands,
wherein the apparatus (100) is configured to conduct the adaptive equalization and/or the time-dynamic equalization by employing the information on the similarity of the signals in each of the one or more frequency bands.

Embodiment 8: An apparatus (100) according to embodiment 6 or 7,
wherein, to determine the similarity information the apparatus (100) is configured to determine an average of a similarity of at least two audio signals in each of a plurality of frequency bands,
wherein the apparatus (100) is configured to conduct the adaptive equalization and/or the time-dynamic equalization by employing the average of the similarity of the signals in each of the plurality of frequency bands.

Embodiment 9: An apparatus (100) according to one of embodiments 6 to 8,
wherein, to determine the similarity information, the apparatus (100) is configured to determine a magnitude-based weighted similarity by conducting a magnitude-based weighting of a similarity of at least two audio signals in each of a plurality of frequency bands,
wherein the apparatus (100) is configured to conduct the adaptive equalization and/or the time-dynamic equalization by employing the magnitude-based weighted similarity.

Embodiment 10: An apparatus (100) according to embodiment 9,
wherein the apparatus (100) is configured to conduct the magnitude-based weighting by employing a weighting function.

Embodiment 11: An apparatus (100) according to embodiment 10,
wherein the weighting function is a sigmoid function.

Embodiment 12: An apparatus (100) according to one of embodiments 9 to 11,
wherein the apparatus (100) is configured to conduct the magnitude-based weighting by employing magnitudes of the plurality of frequency bands to detect, which of the plurality of frequency bands are used to calculate similarity information.

Embodiment 13: An apparatus (100) according to one of embodiments 9 to 12,
wherein the apparatus (100) is configured to conduct the magnitude-based weighting by employing a specific number of frequency bands with a highest magnitude to calculate the similarity information.

Embodiment 14: An apparatus (100) according to one of embodiments 6 to 13,
wherein the apparatus (100) is configured to determine a proper subset of one or more frequency bands from a plurality of frequency bands by employing a magnitude of each of the plurality of frequency bands of the at least two audio signals for determining the proper subset, and
wherein the apparatus (100) is configured to determine the similarity information by determining a similarity information for each of one or more frequency bands of the proper subset without determining similarity information for each of the one or more frequency bands of the plurality of frequency bands which are not comprised by the proper subset.

Embodiment 15: An apparatus (100) according to embodiment 14,
wherein each frequency of the plurality of frequency bands is associated with a magnitude that depends on a magnitude of said frequency band of one or more of the at least two audio signals,
wherein the apparatus (100) is configured to determine the proper subset of one or more frequency bands such that the magnitude being associated with each frequency band of the one or more frequency bands of the proper subset is greater than or equal to the magnitude being associated with each of the one or more frequency bands of the plurality of frequency bands which are not comprised by the proper subset.

Embodiment 16: An apparatus (100) according to one of the preceding embodiments,
wherein the system (200) for reproducing virtual acoustics is configured to conduct cross-talk cancellation by employing a plurality of cross-talk cancellation coefficients,
wherein the apparatus (100) is configured to reduce the spectral distortion by conducting adaptive equalization and/or by conducting time-dynamic equalization using a plurality of equalizer components,
wherein the apparatus (100) is configured to determine the plurality of equalizer components depending on one or more of the plurality of cross-talk cancellation coefficients.

Embodiment 17: An apparatus (100) according to embodiment 16,
wherein the apparatus (100) is configured to determine the plurality of equalizer components by choosing, depending on the cross-talk cancellation coefficients, a pre-calculated set of equalizer components from two or more pre-calculated sets of equalizer components.

Embodiment 18: An apparatus (100) according to embodiment 16, further depending on one of embodiments 6 to 15,
wherein the apparatus (100) is configured to determine the plurality of equalizer components at run-time depending on the similarity information indicating the information on the similarity of the at least two audio signals and/or depending on the plurality of cross-talk cancellation coefficients.

Embodiment 19: An apparatus (100) according to embodiment 16 or 18,
wherein the apparatus (100) is configured to determine the plurality of equalizer components by determining one or more combinations of the plurality of cross-talk cancellation coefficients being a plurality of complex cross-talk cancellation coefficients in a frequency domain.

Embodiment 20: An apparatus (100) according to embodiment 19,
wherein, to determine the one or more combinations of the plurality of cross-talk cancellation coefficients for determining the plurality of equalizer components, the apparatus (100) is configured to determine one or more linear combinations of the complex cross-talk cancellation coefficients in the frequency domain.

Embodiment 21: An apparatus (100) according to embodiment 20,
wherein the apparatus (100) is configured to determine a single correction equalizer from the plurality of equalizer components.

Embodiment 22: An apparatus (100) according to embodiment 21,
wherein the apparatus (100) is configured to determine the single correction equalizer from the plurality of equalizer components by weighting the plurality of equalizer components before combining the plurality of equalizer components to obtain the single correction equalizer.

Embodiment 23: An apparatus (100) according to embodiment 20, further depending one of embodiments 6 to 15,
wherein the apparatus (100) is configured to weight the plurality of equalizer components depending on a similarity value, wherein the similarity value depends on the similarity information.

Embodiment 24: An apparatus (100) according to one of the preceding embodiments,
wherein the apparatus (100) is configured to conduct adaptive equalization and/or by conducting time-dynamic equalization on one or more audio input signals of the system (200) for reproducing the virtual acoustics.

Embodiment 25: An apparatus (100) according to one of the preceding embodiments, further depending on embodiment 2,
wherein the apparatus (100) is configured to conduct adaptive equalization and/or by conducting time-dynamic equalization on two or more audio output signals of the system (200) for reproducing the virtual acoustics.

Embodiment 26: An apparatus (100) according to one of the preceding embodiments,
wherein the apparatus (100) is configured to conduct adaptive equalization and/or by conducting time-dynamic equalization on a cross-talk cancellation filter matrix employed for cross-talk cancellation by the system (200) for reproducing the virtual acoustics.

Embodiment 27: An apparatus (100) according to one of the preceding embodiments, further depending on embodiment 2,
wherein the apparatus (100) is configured to reduce the spectral distortion by conducting the adaptive equalization in a loudness-preserving way, and/or by conducting the time-dynamic equalization in a loudness-preserving way, and/or by adjusting the one or more audio input signals to ensure loudness-preservation.

Embodiment 28: An apparatus (100) according to one of the preceding embodiments,
wherein the apparatus (100) is configured to conduct the adaptive equalization and/or to conduct the time-dynamic equalization by applying an average gain over two or more subbands.

Embodiment 29: A system (200) for reproducing virtual acoustics via loudspeakers, wherein the system (200) comprises:
a loudspeaker signal generator (150) for generating two or more audio output signals from one or more audio input signals,
wherein the system (200) comprises an apparatus (100) according to one of the preceding embodiments for reducing spectral distortion,
wherein the apparatus (100) is configured to reduce the spectral distortion by conducting adaptive equalization and/or by conducting time-dynamic equalization on at least one of the one or more audio input signals and/or on at least one of the two or more audio output signals and/or on filter information employed by the loudspeaker signal generator on the one or more audio input signals or on one or more processed signals which depend on the one or more audio input signals.

Embodiment 30: A system (200) according to embodiment 29,
wherein the system (200) for reproducing virtual acoustics comprises a cross-talk cancellation system for conducting cross-talk cancellation to remove and/or to reduce and/or to avoid cross-talk created by the cross-talk cancellation system when reproducing the virtual acoustics via the loudspeakers,
wherein the apparatus (100) is configured to reduce spectral distortion resulting from conducting the cross-talk cancellation.

Embodiment 31: A system (200) according to embodiment 30,
wherein the one or more audio input signals comprise two binaural audio signals.

Embodiment 32: A system (200) according to one of embodiments 29 to 31,
wherein the system (200) does not comprise the loudspeakers.

Embodiment 33: A system (200) according to one of embodiments 29 to 31,
wherein the system (200) comprises the loudspeakers.

Embodiment 34: A method for reducing spectral distortion in a system (200) for reproducing virtual acoustics via loudspeakers,
wherein the method comprises reducing the spectral distortion by conducting adaptive equalization and/or by conducting time-dynamic equalization.

Embodiment 35: A computer program for implementing the method of embodiment 34 when being executed on a computer or signal processor.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software or at least partially in hardware or at least partially in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitory.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The methods described herein may be performed using a hardware apparatus, or using a computer, or using a combination of a hardware apparatus and a computer.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### LITERATURE

[1] Masiero, B., Fels, J., & Vorländer, M. (2011). Review of the crosstalk cancellation filter technique. Proc. of ICSA, 112.
[2] Kaiser, F. (2011). Transaural Audio-The reproduction of binaural signals over loudspeakers (Doctoral dissertation, Diploma Thesis, Universität für Musik und darstellende Kunst Graz/Institut für Elekronische Musik und Akustik/IRCAM, March 2011).
[3] Choueiri, E. Y. (2008). Optimal crosstalk cancellation for binaural audio with two loudspeakers. Princeton University, 28.
[4] Canfield, G. H., & Kuo, S. M. (1997 September). Dual-Channel Audio Equalization and Cross-Talk Cancellation for Correlated Stereo Signals. In Audio Engineering Society Convention 103. Audio Engineering Society.
[5] U.S. Pat. No. 9,532,156 B2, Apparatus and Method for Sound Stage Enhancement.
[6] U.S. Pat. No. 10,063,984 B2, Method for creating a virtual acoustic stereo system (200) with an undistorted acoustic center.
[7] https://en.wikipedia.org/wiki/Acoustic_space.

1. An apparatus for reducing spectral distortion in a system for reproducing virtual acoustics via loudspeakers,
wherein the apparatus is configured to reduce the spectral distortion by conducting adaptive equalization and/or by conducting time-dynamic equalization.

2. An apparatus according to claim 1,
wherein the apparatus is configured to reduce the spectral distortion by conducting the adaptive equalization and/or by conducting the time-dynamic equalization on at least one of one or more audio input signals of the system for reproducing virtual acoustics, and/or on at least one of two or more audio output signals of the system and/or on filter information to be applied by the system on the one or more audio input signals or on one or more processed signals which depend on the one or more audio input signals.

3. An apparatus according to claim 2,
wherein the apparatus is configured to determine equalization information depending on at least two of the audio input signals and/or depending on at least two of the audio output signals and/or depending on at least two of the processed signals, and wherein the apparatus is configured to conduct the adaptive equalization and/or by conducting the time-dynamic equalization by employing the equalization information; and/or
wherein the system for reproducing virtual acoustics comprises a cross-talk cancellation system for conducting cross-talk cancellation to remove and/or to reduce and/or to avoid cross-talk created by the system when reproducing the virtual acoustics via the loudspeakers, wherein the apparatus is configured to reduce spectral distortion resulting from conducting the cross-talk cancellation; and/or
wherein the apparatus comprises an equalizer, wherein the apparatus is configured to update the equalizer at specific times.

4. An apparatus according to claim 2,
wherein the apparatus is configured to determine similarity information by determining information on a similarity of at least two audio signals, and
wherein the apparatus is configured to conduct the adaptive equalization and/or the time-dynamic equalization using the similarity information,
wherein the one or more audio input signals of the system comprise the at least two audio signals, or wherein the two or more audio output signals of the system comprise the at least two audio signals, or wherein the one or more processed signals comprise the at least two audio signals.

5. An apparatus according to claim 4,
wherein, to determine the similarity information, the apparatus is configured to determine information on a similarity of at least two audio signals in each of one or more frequency bands,
wherein the apparatus is configured to conduct the adaptive equalization and/or the time-dynamic equalization by employing the information on the similarity of the signals in each of the one or more frequency bands.

6. An apparatus according to claim 4,
wherein, to determine the similarity information the apparatus is configured to determine an average of a similarity of at least two audio signals in each of a plurality of frequency bands,
wherein the apparatus is configured to conduct the adaptive equalization and/or the time-dynamic equalization by employing the average of the similarity of the signals in each of the plurality of frequency bands.

7. An apparatus according to claim 4,
wherein, to determine the similarity information, the apparatus is configured to determine a magnitude-based weighted similarity by conducting a magnitude-based weighting of a similarity of at least two audio signals in each of a plurality of frequency bands,
wherein the apparatus is configured to conduct the adaptive equalization and/or the time-dynamic equalization by employing the magnitude-based weighted similarity.

8. An apparatus according to claim 7,
wherein the apparatus is configured to conduct the magnitude-based weighting by employing a weighting function; and/or
wherein the weighting function is a sigmoid function; and/or
wherein the apparatus is configured to conduct the magnitude-based weighting by employing magnitudes of the plurality of frequency bands to detect, which of the plurality of frequency bands are used to calculate similarity information; and/or
wherein the apparatus is configured to conduct the magnitude-based weighting by employing a specific number of frequency bands with a highest magnitude to calculate the similarity information.

9. An apparatus according to claim 4,
wherein the apparatus is configured to determine a proper subset of one or more frequency bands from a plurality of frequency bands by employing a magnitude of each of the plurality of frequency bands of the at least two audio signals for determining the proper subset, and
wherein the apparatus is configured to determine the similarity information by determining a similarity information for each of one or more frequency bands of the proper subset without determining similarity information for each of the one or more frequency bands of the plurality of frequency bands which are not comprised by the proper subset.

10. An apparatus according to claim 9,
wherein each frequency of the plurality of frequency bands is associated with a magnitude that depends on a magnitude of said frequency band of one or more of the at least two audio signals,
wherein the apparatus is configured to determine the proper subset of one or more frequency bands such that the magnitude being associated with each frequency band of the one or more frequency bands of the proper subset is greater than or equal to the magnitude being associated with each of the one or more frequency bands of the plurality of frequency bands which are not comprised by the proper subset.

11. An apparatus according to claim 1,
wherein the system for reproducing virtual acoustics is configured to conduct cross-talk cancellation by employing a plurality of cross-talk cancellation coefficients,
wherein the apparatus is configured to reduce the spectral distortion by conducting adaptive equalization and/or by conducting time-dynamic equalization using a plurality of equalizer components,
wherein the apparatus is configured to determine the plurality of equalizer components depending on one or more of the plurality of cross-talk cancellation coefficients.

12. An apparatus according to claim 11,
wherein the apparatus is configured to determine the plurality of equalizer components by choosing, depending on the cross-talk cancellation coefficients, a pre-calculated set of equalizer components from two or more pre-calculated sets of equalizer components; and/or
wherein the apparatus is configured to determine the plurality of equalizer components by determining one or more combinations of the plurality of cross-talk cancellation coefficients being a plurality of complex cross-talk cancellation coefficients in a frequency domain.

13. A system for reproducing virtual acoustics via loudspeakers, wherein the system comprises:
a loudspeaker signal generator for generating two or more audio output signals from one or more audio input signals,
wherein the system comprises an apparatus according to claim 1 for reducing spectral distortion,
wherein the apparatus is configured to reduce the spectral distortion by conducting adaptive equalization and/or by conducting time-dynamic equalization on at least one of the one or more audio input signals and/or on at least one of the two or more audio output signals and/or on filter information employed by the loudspeaker signal generator on the one or more audio input signals or on one or more processed signals which depend on the one or more audio input signals.

14. A method for reducing spectral distortion in a system for reproducing virtual acoustics via loudspeakers,
wherein the method comprises reducing the spectral distortion by conducting adaptive equalization and/or by conducting time-dynamic equalization.

15. A non-transitory digital storage medium having a computer program stored thereon to perform the method for reducing spectral distortion in a system for reproducing virtual acoustics via loudspeakers,
wherein the method comprises reducing the spectral distortion by conducting adaptive equalization and/or by conducting time-dynamic equalization,
when said computer program is run by a computer.
